(19) United States
(12) Patent Application Publication
(10) Pub. No.: US 2026/0323881 A1
(43) Pub. Date: Oct. 15, 2026

(54) NEAR-UNITY-EMISSIVITY THERMAL RADIATOR

(71) Applicant: City University of Hong Kong, Kowloon (HK)

(72) Inventors: Dangyuan LEI, Kowloon (HK); Yanbo FANG, Kowloon (HK)

(21) Appl. No.: 19/644,035

(22) Filed: Apr. 10, 2026

Related U.S. Application Data
(60) Provisional application No. 63/786,637, filed on Apr. 10, 2025.

(51) Int. Cl. H05K 7/20; B29C 33/38; B29C 33/42; B29C 33/60; B29C 41/12; B29C 41/38; B29C 64/124; B29C 64/30; B29K 83/00; B29L 31/00; B29L 31/18; B33Y 10/00; B33Y 40/20; B33Y 80/00

(52) U.S. Cl. CPC H05K 7/2039; B29C 33/3842; B29C 33/424; B29C 33/60; B29C 41/12; B29C 41/38; B29C 64/124; B29C 64/30; B33Y 10/00; B33Y 40/20; B33Y 80/00; B29K 2083/00; B29L 2031/18; B29L 2031/757

(57) ABSTRACT

The present invention discloses a patterned radiator, which includes a polymer membrane, and a first microscale surface structure formed on the polymer membrane. The radiator achieves near unity emissivity (>0.99) in the atmospheric window with the assistance of micro-3D printing technology. Integrating the radiator into LED lighting system can significantly lower its temperature and improve luminous brightness, which illustrates the application prospects in the field of electronics thermal management.

### FIELD OF INVENTION

This invention relates to thermal radiators, for example radiation coolers for electronic products.

### BACKGROUND OF INVENTION

With the development of semiconductor technology, the increase in the integration of electronic products is also accompanied by an increase in product power consumption. For example, the luminous efficiency of LED tops out at about 60%, which means that in addition to emitting light, nearly half of the energy is consumed in the form of heat. In order to ensure that the temperature rise caused by heat generation affects the normal operation of electronic devices, thermal management of electronic products has now become one of the most important considerations in product design. Usually, the volume of the cooling module of an electronic product directly determines its final size, which directly affects material, storage and transportation costs. Therefore, it is extremely important to find an efficient and compact cooling solution. As a representative passive heat dissipation method that does not require additional energy consumption, radiative cooling is an ideal thermal management solution. Radiative cooling technology utilizes the high thermal radiation characteristics of radiative cooling materials in the long-wavelength infrared range to emit heat into the outer space which is at approximately 3K. This enables temperature control of objects without the need for additional energy consumption. According to the Stefan-Boltzmann law, the thermal radiation power P=Aε(λ,θ)σT⁴, where A, ε(λ,θ), σ, T are surface area, emissivity, Stefan-Boltzmann constant and temperature. It is clear that thermal radiation power is positively related to temperature, surface area and emissivity of the radiation source. It should be noted that emissivity ε(λ, θ) is a function of emission angle θ and wavelength λ, so to achieve a limit thermal radiation performance, the thermal emitter (or radiative cooler) needs to reach unit emissivity at any angle within the atmospheric window (8-13 μm). In this regard, the goal is to approach this emissivity limit as closely as possible.

Metamaterials is a vital option for achieving high-performance thermal emitter due to their artificially controlled emission properties in both bandwidth and emissivity. Raman et. al. fabricated seven layers of HfO₂—SiO₂—HfO₂ film on Ag film, the dielectric layers here are aiming at effectively emit infrared radiation due to phonon-polariton resonance and interference effect. Chae et al. designed a cooler consisted of a simple multilayer structure using inorganic materials such as Al₂O₃, Si₃N₄, and SiO₂, which exhibited high emission property in the 8-13 μm range [24]. The resulting inorganic thermal emitter demonstrated an average emissivity of 87% within the 8-13 μm range and an average absorptivity of 5.2% in the solar spectral region (0.3-2.5 μm). 1D metamaterial design has a great advantage in selective radiative cooling, but few current works can achieve extremely high emissivity. Hossain et al. for the first time utilized the anisotropic conical metamaterial pillars consisting of seven period of metal/dielectric alternating layers (FIG. 3c)) to achieve a highly efficient selective emitter in the atmosphere transparency window [2], but fabricate such a variable cross-section multi-layer stacking structure is hard and costly. Zhang et al. mixed Al₂O₃ in PDMS, and prepared pyramid-shaped surface microstructures [20]. The artificial hierarchical structure shows a high emissivity of 96% and solar reflectance of 95%. The infrared emission property is good but does not reach the theoretical limit. For comparison, Song et al. fabricated a cavity resonance basing 2D grating with ultrahigh emissivity in atmospheric window [16]. Although a near-unity emissivity is achieved, the angular dependence of emissivity is not discussed and the pillar shaped structure is usually poor at omnidirectional emission. The metamaterial described in the above research is mainly processed through vapor deposition, photolithography and other methods. Although these processing methods are mature, the processing cost is still high, and the structural complexity is limited by the processing technology. In summary, there is an urgent need to propose a radiation cooler with simple processing and omnidirectional ultra-high emissivity.

### REFERENCES

The following references are referred to throughout this specification, as indicated by the numbered brackets. The disclosures of each of these references are hereby incorporated by reference herein in their entireties for all purposes.
[1] Herve, A.; Drevillon, J.; Ezzahri, Y.; Joulain, K. Radiative cooling by tailoring surfaces with microstructures: Association of a grating and a multi-layer structure. Journal of Quantitative Spectroscopy and Radiative Transfer 2018, 221, 155-163. DOI: 10.1016/j.jgsrt.2018.09.015.
[2] Hossain, M. M.; Jia, B.; Gu, M. A Metamaterial Emitter for Highly Efficient Radiative Cooling. Advanced Optical Materials 2015, 3 (8), 1047-1051. DOI: 10.1002/adom.201500119.
[3] Jeon, D. J.; Ji, S.; Lee, E.; Kang, J.; D'Alba, L.; Shawkey, M. D.; Yeo, J. S. How the Eurasian Jay Expands its Color Palette by Optimizing Multiple Scattering. Advanced Optical Materials 2022, 11 (4). DOI: 10.1002/adom.202202210.
[4] Jeong, S. Y.; Tso, C. Y.; Wong, Y. M.; Chao, C. Y. H.; Huang, B. Daytime passive radiative cooling by ultra emissive bio-inspired polymeric surface. Solar Energy Materials and Solar Cells 2020, 206. DOI: 10.1016/j.solmat.2019.110296.
[5] King, J.; Wan, C.; Park, T. J.; Deshpande, S.; Zhang, Z.; Ramanathan, S.; Kats, M. A. Electrically tunable VO2-metal metasurface for mid-infrared switching, limiting and nonlinear isolation. Nature Photonics 2023. DOI: 10.1038/s41566-023-01324-8.
[6] Kusunoki, F.; Kohama, T.; Hiroshima, T.; Fukumoto, S.; Takahara, J.; Kobayashi, T. Narrow-Band Thermal Radiation with Low Directivity by Resonant Modes inside Tungsten Microcavities. Japanese Journal of Applied Physics 2004, 43 (8R). DOI: 10.1143/jjap.43.5253.
[7] Lee, E.; Luo, T. Black body-like radiative cooling for flexible thin-film solar cells. Solar Energy Materials and Solar Cells 2019, 194, 222-228. DOI: 10.1016/j.solmat.2019.02.015.
[8] Li, P.; Liu, B.; Ni, Y.; Liew, K. K.; Sze, J.; Chen, S.; Shen, S. Large-Scale Nanophotonic Solar Selective Absorbers for High-Efficiency Solar Thermal Energy Conversion. Adv Mater 2015, 27 (31), 4585-4591. DOI: 10.1002/adma.201501686 From NLM PubMed-not-MEDLINE.
[9] Li, S. X.; Xu, Y. S.; Li, C. L.; Guo, Q.; Wang, G.; Xia, H.; Fang, H. H.; Shen, L.; Sun, H. B. Perovskite Single-Crystal Microwire-Array Photodetectors with Performance Stability beyond 1 Year. Adv Mater 2020, 32 (28), e2001998. DOI: 10.1002/adma.202001998 From NLM PubMed-not-MEDLINE.
[10] Lin, K.-T.; Nian, X.; Li, K.; Han, J.; Zheng, N.; Lu, X.; Guo, C.; Lin, H.; Jia, B. Highly efficient flexible structured metasurface by roll-to-roll printing for diurnal radiative cooling. eLight 2023, 3 (1). DOI: 10.1186/s43593-023-00053-3.
[11] Liu, V.; Fan, S. S4: A free electromagnetic solver for layered periodic structures. Computer Physics Communications 2012, 183 (10), 2233-2244. DOI: 10.1016/j.cpc.2012.04.026.
[12] Liu, Y.; Liu, R.; Qiu, J.; Wang, S. 4D printing of thermal responsive structure for environmentally adaptive radiative cooling and heating. Journal of Advanced Manufacturing and Processing 2021, 4 (2). DOI: 10.1002/amp2.10107.
[13] Lu, Y.; Chen, Z.; Ai, L.; Zhang, X.; Zhang, J.; Li, J.; Wang, W.; Tan, R.; Dai, N.; Song, W. A Universal Route to Realize Radiative Cooling and Light Management in Photovoltaic Modules. Solar RRL 2017, 1 (10). DOI: 10.1002/solr.201700084.
[14] Qarony, W.; Hossain, M. I.; Dewan, R.; Fischer, S.; Meyer-Rochow, V. B.; Salleo, A.; Knipp, D.; Tsang, Y. H. Approaching Perfect Light Incoupling in Perovskite and Silicon Thin Film Solar Cells by Moth Eye Surface Textures. Advanced Theory and Simulations 2018, 1 (8). DOI: 10.1002/adts.201800030.
[15] Qing, Y. M.; Wang, H.; Lei, D. Wide-angle ultrabroadband absorption in black phosphorus/dielectric multilayer anisotropic metamaterials. Journal of Optics 2024. DOI: 10.1088/2040-8986/ad3cee.
[16] Song, J.; Seo, J.; Han, J.; Lee, J.; Lee, B. J. Ultrahigh emissivity of grating-patterned PDMS film from 8 to 13 μm wavelength regime. Applied Physics Letters 2020, 117 (9). DOI: 10.1063/5.0017838.
[17] Song, J.; Si, M.; Cheng, Q.; Luo, Z. Two-dimensional trilayer grating with a metal/insulator/metal structure as a thermophotovoltaic emitter. Appl Opt 2016, 55 (6), 1284-1290. DOI: 10.1364/AO.55.001284 From NLM PubMed-not-MEDLINE.
[18] Wang, T.; Wu, Y.; Shi, L.; Hu, X.; Chen, M.; Wu, L. A structural polymer for highly efficient all-day passive radiative cooling. Nat Commun 2021, 12 (1), 365. DOI: 10.1038/s41467-020-20646-7 From NLM PubMed-not-MEDLINE.
[19] Wu, D.; Liu, C.; Xu, Z.; Liu, Y.; Yu, Z.; Yu, L.; Chen, L.; Li, R.; Ma, R.; Ye, H. The design of ultra-broadband selective near-perfect absorber based on photonic structures to achieve near-ideal daytime radiative cooling. Materials & Design 2018, 139, 104-111. DOI: 10.1016/j.matdes.2017.10.077.
[20] Zhang, H.; Ly, K. C. S.; Liu, X.; Chen, Z.; Yan, M.; Wu, Z.; Wang, X.; Zheng, Y.; Zhou, H.; Fan, T. Biologically inspired flexible photonic films for efficient passive radiative cooling. Proc Natl Acad Sci USA 2020, 117 (26), 14657-14666. DOI: 10.1073/pnas.2001802117 From NLM PubMed-not-MEDLINE.
[21] Zhou, J.; Chen, T. G.; Tsurimaki, Y.; Hajj-Ahmad, A.; Fan, L.; Peng, Y.; Xu, R.; Wu, Y.; Assawaworrarit, S.; Fan, S.; et al. Angle-selective thermal emitter for directional radiative cooling and heating. Joule 2023. DOI: 10.1016/j.joule.2023.10.013.
[22] Zhu, L.; Raman, A.; Wang, K. X.; Anoma, M. A.; Fan, S. Radiative cooling of solar cells. Optica 2014, 1 (1). DOI: 10.1364/optica.1.000032.
[23] Zou, C.; Ren, G.; Hossain, M. M.; Nirantar, S.; Withayachumnankul, W.; Ahmed, T.; Bhaskaran, M.; Sriram, S.; Gu, M.; Fumeaux, C. Metal-Loaded Dielectric Resonator Metasurfaces for Radiative Cooling. Advanced Optical Materials 2017, 5 (20). DOI: 10.1002/adom.201700460.
[24] Chae, D., Kim, M., Jung, P. H., Son, S., Seo, J., Liu, Y., . . . & Lee, H. (2020). Spectrally selective inorganic-based multilayer emitter for daytime radiative cooling. ACS applied materials & interfaces, 12(7), 8073-8081.

### SUMMARY OF INVENTION

Accordingly, the present invention, in one aspect, is a patterned radiator, which includes a polymer membrane, and a first microscale surface structure formed on the polymer membrane.

In some embodiments, the polymer membrane is made of polydimethylsiloxane (PDMS).

In some embodiments, the first microscale surface structure comprises a plurality of micro-pyramids.

In some embodiments, the base angle of each said micro-pyramid equals to or is larger than 54.75°.

In some embodiments, the radiator is adapted to achieve an infrared emissivity of greater than 0.95 in an atmosphere window.

In some embodiments, the radiator has a thickness of 200 μm or less.

In some embodiments, the radiator has a thickness of 100 μm or less.

In some embodiments, the radiator is flexible and stretchable.

According to another aspect of the invention, there is provided a method for fabricating a template for making the patterned radiator. The method includes the steps of using a 3D printing process the template which comprises a second microscale surface structure; and surface-treating the template to reduce a demolding force.

In some embodiments, the second microscale surface structure includes a plurality of inverted micro-pyramids.

In some embodiments, the 3D printing process is a Projection Micro Stereolithography (PμSL) process.

In some embodiments, in the surface-treating step FOTS (1H,1H,2H,2H-Perfluorooctyltriethoxysilane) is used.

According to a further aspect of the invention, there is provided a method of producing a patterned radiator. The method incudes the steps of: providing a template that includes a plurality of second microscale surface structure; spin-coating a degassed prepolymer on the template; and curing and separating a patterned radiator from the template.

In some embodiments, the degassed prepolymer is a degassed PDMS prepolymer.

In some embodiments, the degassed PDMS prepolymer is mixed with a base and a curing agent.

In a further aspect of the invention, there is provided a high-performance patterned radiator, which includes a polymer membrane, and a microscale surface structure with a variable cross-section design. The radiator exhibits near-unit emissivity within the long-wave infrared spectrum (8-13 μm) and is capable of broad angular thermal emission performance.

In some embodiments, the microscale structure is fabricated using a 3D-printed template, with design parameters including grating period, width, and height optimized for enhanced emissivity.

In some embodiments, the microscale surface structure reduces impedance mismatch between air and the radiator material, enabling decreased reflectance and improved absorption efficiency.

In some embodiments, cavity resonance effects induced by the pyramid geometry enhance electromagnetic wave absorption in regions with small extinction coefficients, further improving thermal emission efficiency.

In some embodiments, the polymer material exhibits high long-wave infrared absorption properties due to its molecular structure.

In some embodiments, the manufacturing process involves fabricating a template with micro-pyramid structures using a microscale or nanoscale 3D printing process, surface-treating the template to reduce demolding forces, spin-coating a degassed prepolymer onto the template, and curing and separating the patterned PDMS membrane to form the radiator.

In some embodiments, the radiator enhances cooling power by increasing spectral and angular emissivity, thus providing efficient heat dissipation in compact systems.

In some embodiments, the surface design reduces the effects of environmental thermal disturbances by stabilizing thermal emission performance.

In some embodiments, the patterned radiator further includes a superhydrophobic surface treatment to enhance durability and functionality in harsh environmental conditions.

One can see that exemplary embodiments of the invention therefore provide a high-performance patterned radiator with near-unity emissivity and excellent angular performance, achieved through a micro-pyramid surface structure on a polymer membrane. This design effectively addresses both impedance mismatch and absorption inefficiencies in long-wave infrared (LWIR) wavelengths (8-13 μm), commonly referred to as the atmospheric window. The aim is to improve the emissivity in atmospheric window to maximum within a widest possible angle range. As a microscale 3D printing technology, Projection Micro Stereolithography (PμSL) technology is used due to its high resolution ranging from 0.6 μm to 30 μm and relatively wide printing area up to ~90 μmm*50 mm. PμSL's high plane resolution and layered manufacturing features give it excellent processing resolution and complexity, which provides a high degree of design freedom. The surface structure is optimized with Rigorous coupled-wave analysis (RCWA) and a suitable dimension is chosen for PμSL processing. The prepared sample exhibits a near-unity ε (>0.99) in atmospheric window and keep a high ε(0) within the angle region of 0°-80°. Experiment shows that integrating the large-angle near-unit emissivity thermal emitter into a LED lighting system can significantly lower its temperature and improve luminous brightness, which illustrates the application prospects of the results of the LANE-RC (Large Angle Near-unity Emissivity Radiative Cooler) in the field of electronics thermal management.

The foregoing summary is neither intended to define the invention of the application, which is measured by the claims, nor is it intended to be limiting as to the scope of the invention in any way.

### BRIEF DESCRIPTION OF FIGURES

The foregoing and further features of the present invention will be apparent from the following description of embodiments which are provided by way of example only in connection with the accompanying figures, of which:

FIG. 1a shows a schematic illustration of key features of the LANE-RC according to an embodiment of the invention.

FIG. 1b shows emissivity of the structured PDMS membrane as a function of unit width and tilt angle (alpha).

FIG. 2a is a schematic illustration of the preparation process of LANE-RC.

FIG. 2b shows water contact angle of plain PDMS and LANE-RC.

FIG. 2c shows the scanning electron microscope image of the surface of LANE-RC at a first viewing angle, at a resolution of 100 μm.

FIG. 2d shows the scanning electron microscope image of the surface of LANE-RC at a second viewing angle, at a resolution of 100 μm.

FIG. 2e shows the scanning electron microscope image of the surface of LANE-RC at the second viewing angle, at a resolution of 20 μm.

FIG. 3a shows measured emissivity of plain PDMS and LANE-RC membrane.

FIG. 3b illustrates the complex refractive index of PDMS.

FIG. 3c illustrates schematic diagram of anti-reflective properties of surface structures.

FIG. 3d1 is a schematic of the cross-section location of a surface structure.

FIG. 3d2 shows the electric field distribution of the surface structure at the wavelength of ~9.5 μm.

FIG. 3d3 shows the electric field distribution of the surface structure at the wavelength of ~10.2 μm.

FIG. 3d4 shows the electric field distribution of the surface structure at the wavelength of ~12.5 μm.

FIG. 3e shows the emissivity as a function of azimuthal angle θ and polar angle φ, i.e. ε(θ,φ).

FIG. 3f illustrates apparent temperature of LANE-RC in a series of azimuthal angles θ, the temperature of the sample is constant at 35° C. (The lower the apparent temperature, the lower the emissivity).

FIG. 4a is a schematic diagram of a testing setup of the LANE-RC applied lighting LED passive cooling testing.

FIG. 4b shows the temperature variation with testing time for both groups, with the right side of the figure being partial enlargement of the colored areas on the left side.

FIG. 4c shows the illuminance variation with testing time for both groups, with the right side of the figure being partial enlargement of the colored areas on the left side.

### DETAILED DESCRIPTION

As mentioned above, thermal management stands as a pivotal aspect within the contemporary electronics industry, dictating the extent of integration, multifunctionality, and miniaturization achievable in electronic devices. With the continual enhancement in performance and reduction in power consumption of electronic products, effective thermal management assumes an increasingly critical role. Particularly, outdoor electronics face substantial operating temperature differentials and endure harsh environmental conditions, necessitating the development of efficient, reliable, and compact heat dissipation techniques.

A first embodiment of the invention therefore introduces a thermal emitter characterized by near-unity long-wave infrared emissivity alongside minimal angle sensitivity and superhydrophobic properties. Using 3D printing technology, a thermal emitter is fabricated with omnidirectional near-unity long-wave infrared emissivity and superhydrophobicity, tailored specifically for the thermal management of outdoor electronics. The emission properties and wide-angle high emissivity enable a substantial temperature reduction exceeding 23° C., coupled with a 23.6% enhancement in brightness for a lighting LED. These findings present avenues for the thermal management of outdoor electronic devices while broadening the spectrum of processing options for long-wave infrared functional devices.

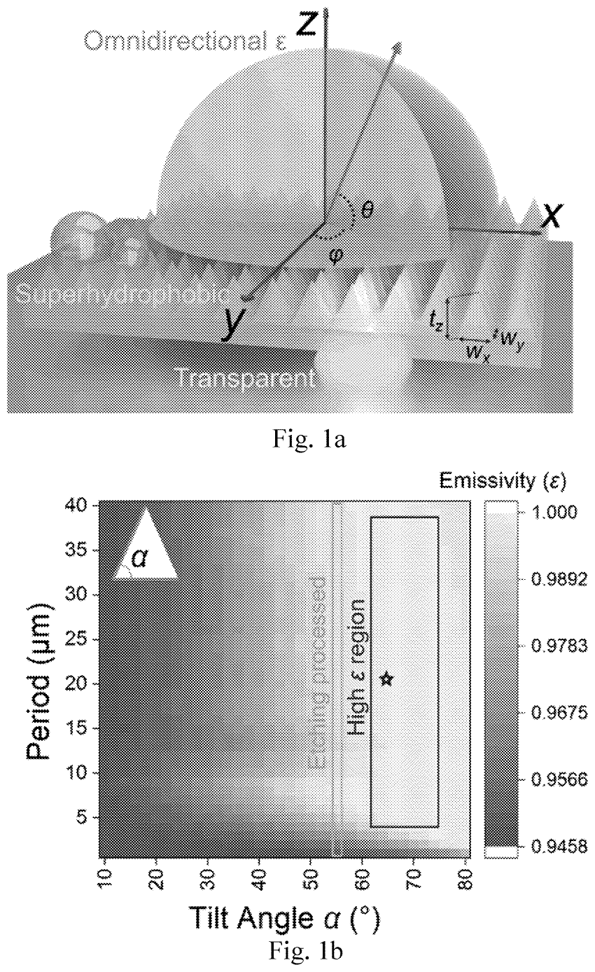

The high-performance radiator features a patterned microscale structure on a flexible polymer membrane, as generally illustrated in FIG. 1a. The high-performance radiator achieves near-unity emissivity across a broad angular range within the atmospheric window (8-13 μm), making it highly effective for thermal radiation management. The microscale structure addresses impedance mismatch and enhances light trapping, improving absorption and emission efficiency in both high and low extinction coefficient regions. Key functions of the radiator include:
Enhanced Radiative Heat Dissipation: The radiator significantly reduces thermal resistance by improving hemispherical and spectral emissivity, providing superior cooling performance under thermal radiation principles.
Wide-Angle Performance: The angular insensitivity of the emissivity ensures effectiveness across varying incident angles, optimizing thermal management even in dynamic environments.
Durability and Process Scalability: The polymer-based membrane offers flexibility, chemical stability, and adaptability for various processing techniques, including precision 3D printing for structural optimization.

Advantages of the radiator as compared to existing technology/products include but not limited to the followings:
Near-Unity Emissivity with Wide Angular Range
   The patterned microscale structure achieves near-unity emissivity within the atmospheric window (8-13 μm), surpassing traditional flat or constant cross-section designs. Its ability to maintain high emissivity across a wide angular range improves thermal radiation efficiency under diverse operational conditions.
Enhanced Heat Dissipation Through Advanced Mechanisms
   The microscale structure effectively reduces impedance mismatch at high extinction coefficient regions, minimizing reflection and maximizing absorption.
   For low extinction coefficient regions, the structure promotes cavity resonance, enhancing absorption efficiency.
These mechanisms deliver superior radiative cooling performance compared to existing flat or resonance-only designs.
Scalability and Customization with Flexible Polymer Materials
   The use of polymer membranes provides flexibility, durability, and chemical resistance, unlike rigid materials such as etched silicon. Additionally, scalable manufacturing processes is supported, including precision 3D printing, allowing customization for various applications.
Improved Performance Stability and Thermal Shock Resistance
   The radiator not only dissipates heat more effectively but also adds thermal capacity, stabilizing temperatures in dynamic environments. This feature mitigates issues like thermal shocks, which are common in conventional solutions, enhancing overall system reliability.
Compact and Lightweight Design
   Unlike traditional bulky cooling systems, the thin and lightweight structure enables integration into compact devices without compromising cooling performance. This advantage is critical for portable or space-constrained applications.
Versatility Across Applications
   Exemplary embodiments of the invention are adaptable for diverse thermal management needs in industrial, optical, and outdoor systems. Its wide applicability contrasts with existing technologies that often target specific use cases or require specialized materials.
Cost-Effective Manufacturing
   The integration of polymer materials and 3D printing significantly reduces production costs compared to conventional methods such as silicon etching. This makes the invention economically viable for large-scale deployment.

By addressing the limitations of existing technologies with advanced emissivity, scalability, and stability, this radiator offers a superior solution for efficient and versatile thermal management.

Therefore, the radiator represents a versatile, scalable, and high-performance solution for thermal management challenges across various fields. Applications of the radiator include but not limited to:
Thermal Management in Harsh Environments: The device's ability to efficiently radiate heat while withstanding extreme temperature differentials makes it suitable for outdoor systems exposed to challenging climates.
Compact Thermal Management Systems: Its lightweight and flexible design enables integration into compact devices, improving efficiency without increasing form factor.
Enhanced System Stability: By maintaining stable thermal performance, the invention supports applications sensitive to temperature fluctuations, improving overall system reliability.
Scalable Manufacturing for Diverse Uses: The flexible manufacturing approach allows customization for a broad range of industrial, medical, and optical applications.

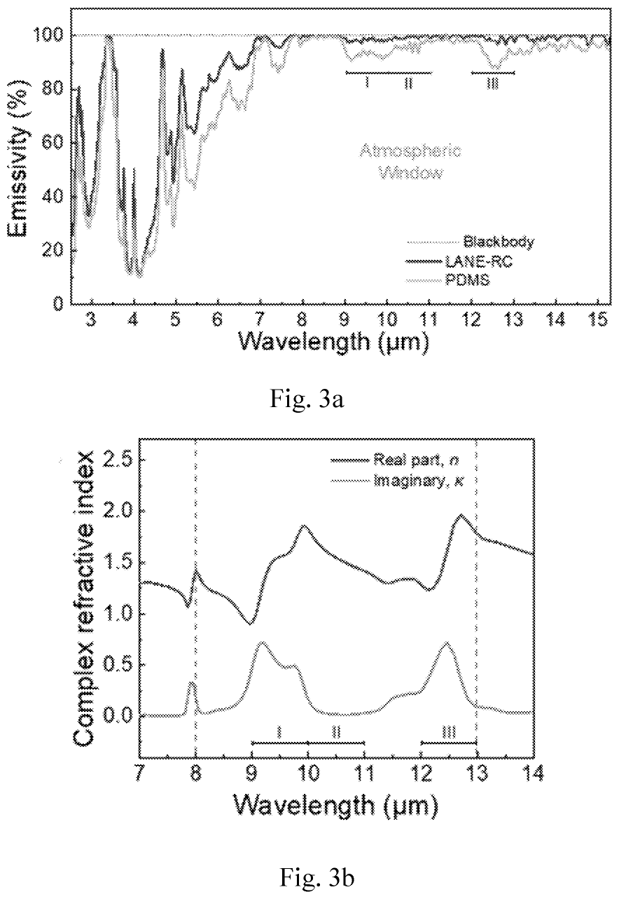

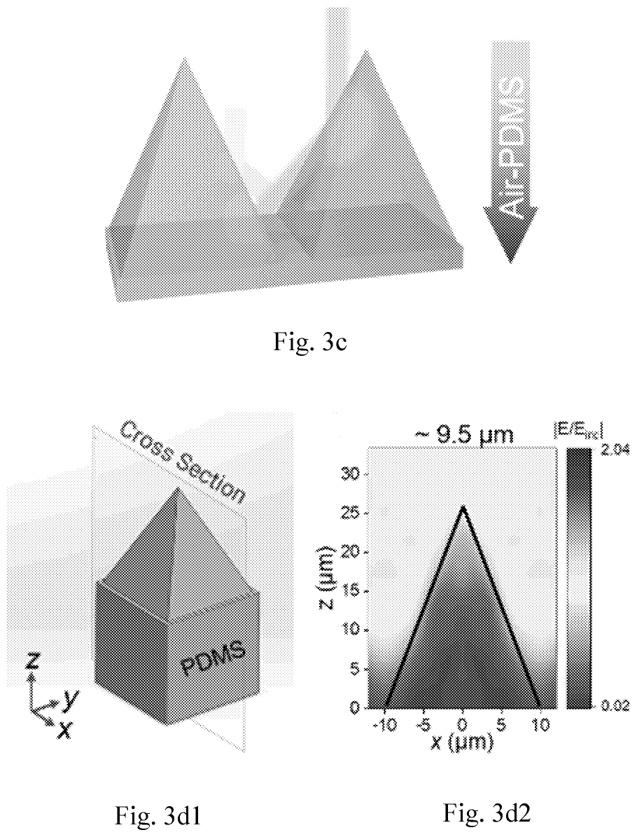

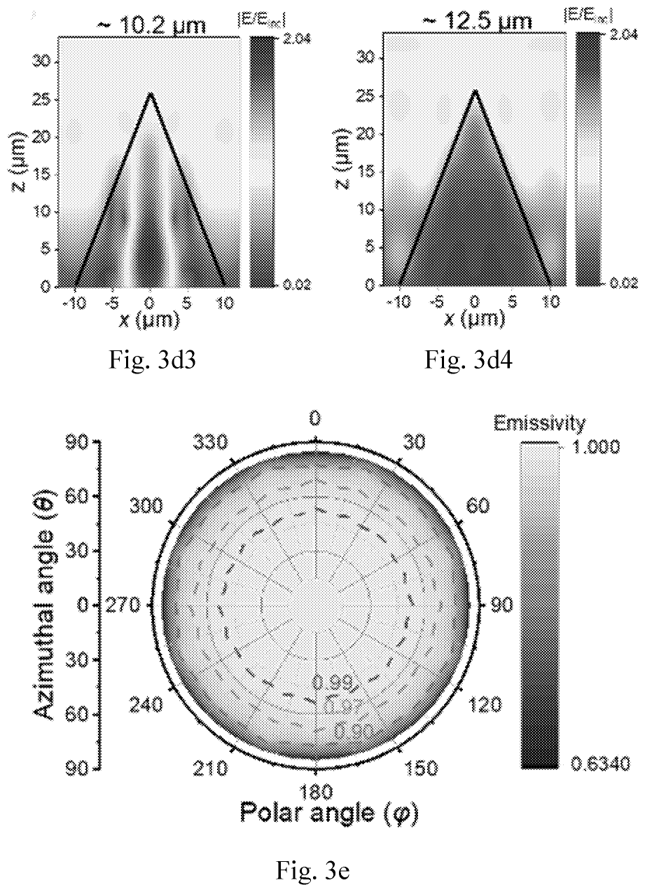

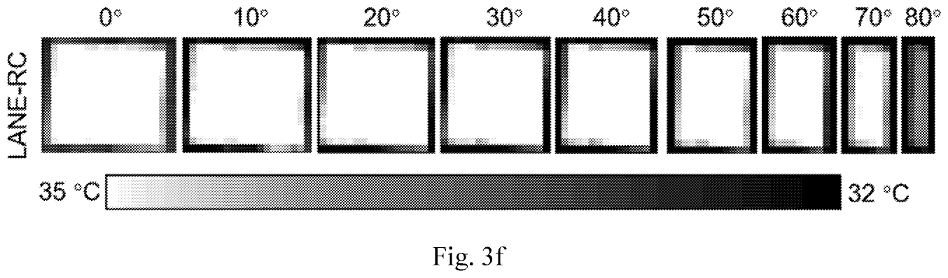

As shown in FIG. 1b, 2D gratings on polydimethylsiloxane (PDMS) membrane is provided. In FIG. 1b, the high emissivity region is highlighted with a rectangular, darker wireframe on the far-right side, while the structures fabricated through silicon etching are indicated with a strip-shaped, lighter wireframe. PDMS has various advantages including flexibility, chemical inertness, biocompatibility, and ease of processing, making it suitable for medical, optical, electronic, and other fields. Due to its massive Si—O—Si covalent bond content, PDMS exhibits high absorptance around 8-13 μm, which is well known as atmospheric window, makes it an ideal material for our research. Surface structure we used in this embodiment is determined to be micro-pyramids, which is widely used in light trapping industries that enhance photovoltaic conversion efficiency. 3D dimension of unit structure is illustrated in FIG. 1a. In this exemplary embodiment, four design parameters, i.e. grating period (A), grating width (w_{g}), grating height (t_{g}), are used to optimize the emission performance of LANE-RC. A is determined as 26 μm, w_{g} is 24 μm and t_{g} is 25 μm. The structural parameters are determined with rigorous coupled-wave analysis (RCWA) at 10 μm. Typically, pyramid structures are processed with pattern transfer from alkaline etched silicon template. Due to the crystallographic properties of silicon, the base angle of pyramid is locked at 54.75°, which means the ratio of t_{g}/w_{g} is strictly determined. As shown in FIG. 3c, traditionally processed thermal emitter cannot achieve an ideal emissivity, while LANE-RC breaks through the limitation of unit aspect ratio and achieving higher emissivity.

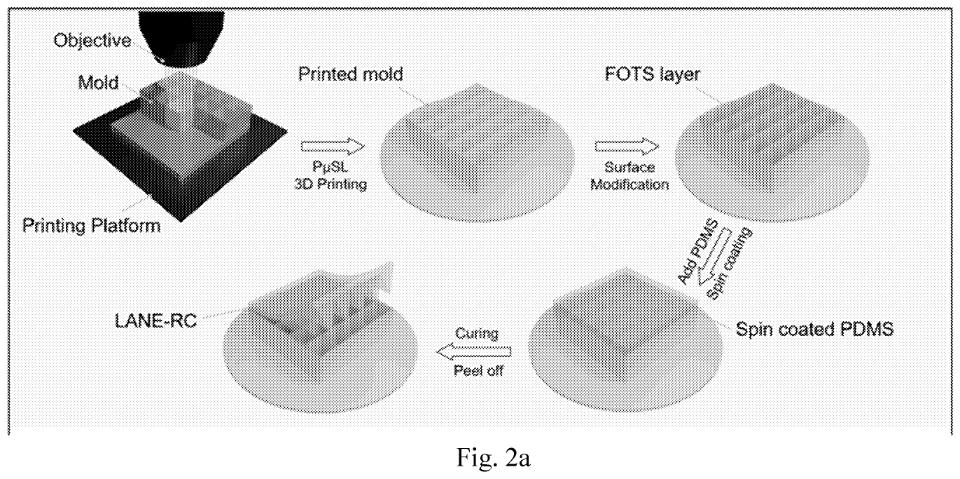

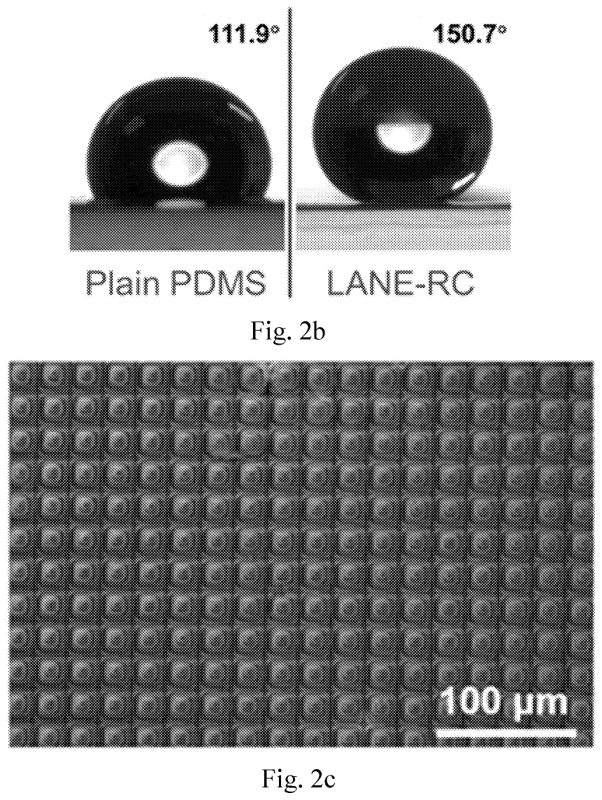

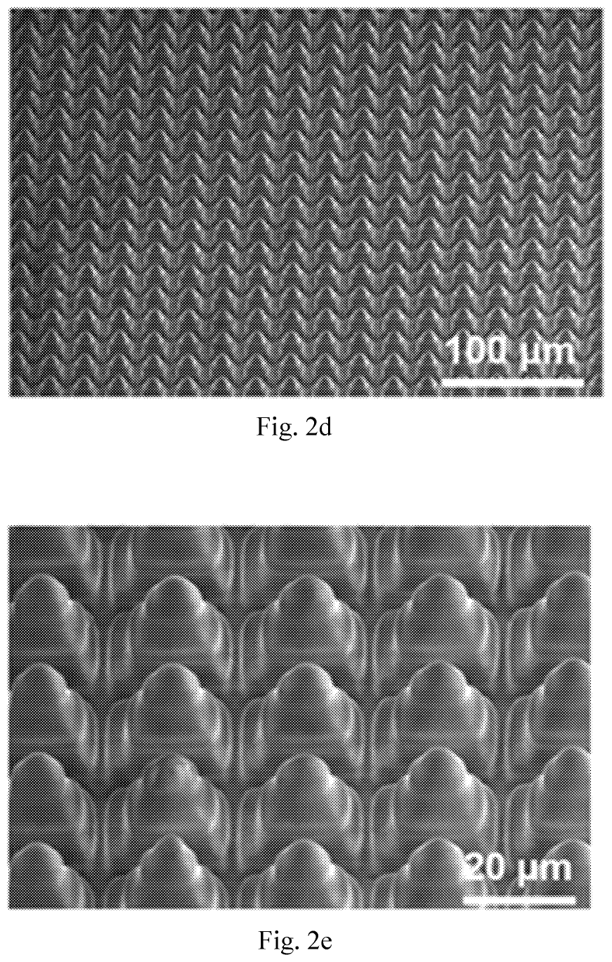

Based on the described structure above, a high-emissivity patterned thermal emitter, named LANE-RC, was prepared using a 3D-printed template for replication, as shown in FIGS. 2a-2e. The template was fabricated through the PμSL 3D printing process, utilizing a BMF S130 printer with an exposure accuracy of 2 μm and a minimum layer thickness of 5 μm. The inverted pyramid structures in the 3D-printed template were obtained by exposing the template to five layers, resulting in block-approximated near-inverted pyramid structures (FIG. 2a). Prior to the replication process, the template was surface-treated using FOTS (1H,1H,2H,2H-Perfluorooctyltriethoxysilane) to reduce the demolding force. Subsequently, a degassed PDMS prepolymer, mixed with a base and curing agent (Sylgard 184, DowCorning) in a 10:1 weight ratio, was poured onto the template and spin-coated to form an approximately 100 μm thick membrane, followed by curing on a 70° C. hotplate for two hours. Finally, the LANE-RC membrane was separated. The surface morphology of LANE-RC is shown in FIGS. 2b-2e, displaying that the shapes of micro-pyramids are well prepared and highly consisted. For each pyramid, it shows block-approximated appearance while the shape of block is not as clear as designed, whose shape is mainly due to two reasons. The first reason is the diffraction phenomenon at the edge of the light modulated by DMD (Digital Micromirror Devices) causes a slight deviation between the image projected on the resin and the digital mask during 3D printing, softening the outer contour of the printed template. The second reason is the impact of vacuum degree on the morphology during PDMS forming. A large number of studies have shown that the vacuum degree will affect the degree of fit between PDMS and the template, thereby directly affecting the morphology of the obtained PDMS structure. The smoothed surface makes the prepared surface structure closer to the ideal pyramid structure.

The emission property of LANE-RC has been characterized with FTIR integrated with an integrating sphere. A LANE-RC sample is placed on an aluminum plate and its reflectance is directly measured with the FTIR. It is clear that the absorptance, reflectance and transmittance of matter obeys,

A=1−T~R (1)
where A, R and T refer to absorptance, reflectance and transmittance, respectively. Aluminum plate is highly reflective in infrared spectrum and barely no transmission, T can be regarded as 0. Furthermore, according to Kirchhoffs law of thermal radiation, Under thermal equilibrium conditions, the thermal radiation absorptance and emittance of an object are strictly equal. Therefore, the absorptance can be obtain by measuring the reflectance of the sample. The emittance of the samples are then compared with that of an approximated black body, which is a model classical small hole on a cavity, and obtain the actual thermal radiation curve at room temperature. The thermal radiation curve is shown in FIG. 3a, while the blue background shows the atmospheric window which stands for the transparency of the atmosphere. It shows that LANE-RC has an overall higher emittance in atmosphere window (8-13 μm) and the emissivity of LANE-RC in this region is 99.1% comparing that of 95.2% for a plain PDMS membrane at same thickness. At the wavelength range of 8-13 μm, plain PDMS membrane shows dips in around 9-10 μm and 12-13 μm, and a depression in 10-11 μm region.

As shown in FIG. 3b, the imaginary part of refractive index, known as extinction coefficient (k), surges in around 9-10 μm and 12-13 μm. Big extinction coefficient leads to a strong impedance mismatch between air and PDMS, which cause reflectivity enhancement in these two regions and leads to the appearance of two dips. While the extinction coefficient in 10-11 μm region is small, which leads to a relatively weak absorption/emission property. The electromagnetic waves in this band cannot be fully absorbed, which caused the existence of the depression. For summarize, in the band range with high extinction coefficient, although the material has strong absorption performance and electromagnetic waves can be absorbed within a short distance, the interface reflection is high due to the impedance mismatch with free space; while in the band with small light coefficient, Within the range, electromagnetic waves are more likely to enter the material, but the material's absorption efficiency is low and cannot be completely absorbed. The surface pyramid structure on LANE-RC successively solved these two questions with the help of several mechanisms.

For big k regions, decrease the impedance mismatch is a must. The pyramid structure here is effective for reduce reflection. Due to the tilted surface of pyramid structure, the propagating direction of incident light is deflected and interact with Air-medium interface. Each time the light incident, its energy is absorbed once. In big k regions, light can be effectively absorbed on the very surface, lead to a large electric field strength gradient from surface to center with a near-zero electric field strength in the center. This multiple scattering effect greatly inhibits the reflection, and the increased transmitted light is effectively absorption by the intrinsic high absorption characteristics of PDMS in this band allow this additional incident light to be efficiently absorbed internally. Additionally, the variable cross-section characteristics shown in FIGS. 3d1-3d4, as the corresponding electric field distributions at the cross section of cones created a transition region between air and medium, created a smooth gradient of refractive index, eases impedance mismatch between medium and air, reduce the reflection at the same time.

Besides the anti-reflection property of LANE-RC, other mechanisms also affect the absorption behavior of small k region, i.e. 9-10 μm and 12-13 μm. The corresponding electric field distributions are shown in FIG. 3f. It is clear that the electric field in the pyramid unit is enhanced at the wavelength of around 8.2 μm and 10 μm, but the electric field density at around 9.5 μm is much lower than free space. Electromagnetic waves that enters the medium will continue to propagate in the medium and interact with the medium at the same time. The enhancement of the electric field at 8.2 μm and 10 μm is mainly due to the cavity resonance. The gradient lateral size characteristics of the pyramid structure bring unique resonance response characteristics, making the entire structure have a good cavity resonance effect in a wide range. This effect can significantly enhance the electromagnetic wave absorption in the surface area. For 9.5 μm, the electric field strength weakens rapidly with depth from the surface with no obvious resonance enhancement effect. This is mainly due to the small penetration depth δ_{λ} of PDMS. Penetration depth defines the depth of the intensity of electromagnetic radiation decrease to 1/e of its original value. The penetration depth is calculated with

$${δ}_{λ} = \frac{λ}{4 π κ}$$

where κ is extinction coefficient. It is clear that a larger extinction coefficient leads to a smaller penetration depth, which means a higher absorption efficiency. Due to the high absorption efficiency. The penetration depth at 9.5 μm is much smaller than that of 8.2 m and 10 μm. Therefore, even if the conditions for cavity resonance generation are also met at this wavelength, due to the strong absorption of electromagnetic waves of this wavelength by PDMS, the electric field enhancement cannot be generated in the center of the pyramid unit.

Other bands are less affected than atmospheric window band. The absorptance & emissivity of LANE-RC are still stronger than that of plane PDMS from 5 μm to 8 μm, but the emissivity has not reached the level of near-unity. This is mainly due to the mismatch of pyramid structure and the wavelength of light; the scattering effect and resonance effect are significantly weaker than that of atmospheric window band. This property can reduce the impact of the surrounding thermal environment on the thermal emitter and improve the actual cooling performance of the thermal emitter.

It is clear that the cooling power of a thermal emitter is calculated by,

P_{cool}(T)=Pₑₘᵢ(T)~Pₐₜₘ(T_{amb})~Pₛᵤₙ~P_{cond+conv}

where Pₐₜₘ(T_{amb}), Pₛᵤₙ, P_{cond+conv} are the thermal power received from atmospheric thermal radiation, daytime sunlight radiation and heat conduction and convection from environment. Pₑₘᵢ(T) is the emission power of thermal emitter, which is given by,

$${P}_{emi} ( T ) = A \int d Ω cos θ {\int }_{0}^{∞} d λ {I}_{BB} ( T , λ ) ε ( λ , θ )$$

where I_{BB}(T,λ) stands for the black body specific intensity at temperature T and wavelength λ. ε(λ,θ) is the spectral and angular emissivity. A is the surface area of the thermal emitter. f di equals to

$$\int d Ω = {\int }_{0}^{π / 2} sin θ d θ {\int }_{0}^{2 π} d ϕ$$

and θ is any angle between 0 to π/2 and φ is any angle between 0 to 2π.

A higher Pₑₘᵢ(T) directly increase the overall cooling power of a thermal emitter, and a near unity spectral and angular emissivity ε(λ,θ) raises Pₑₘᵢ(T) to limit. As shown in FIG. 3c, the emissivity in the hemispheric space is significantly higher than Plain PDMS and pure resonance based PDMS metasurface. As shown in FIG. 3e, when 0 smaller than ~78° and 82°, the emissivity of LANE-RC is above 0.95 and 0.90 respectively. The spectral and angular emissivity ε(λ,θ) is significantly higher than that of plain PDMS and pure resonance based PDMS metasurface. Since the resonance condition of 2D gratings is very sensitive to angles, when the theta angle is large, its emissivity is difficult to maintain. Since the pyramid structure has a good light trapping effect in a wide-angle range, and its variable cross-section feature has better resonance response in a wide frequency range than a constant cross-section, LANE-RC has excellent hemispheric space high emissivity properties.

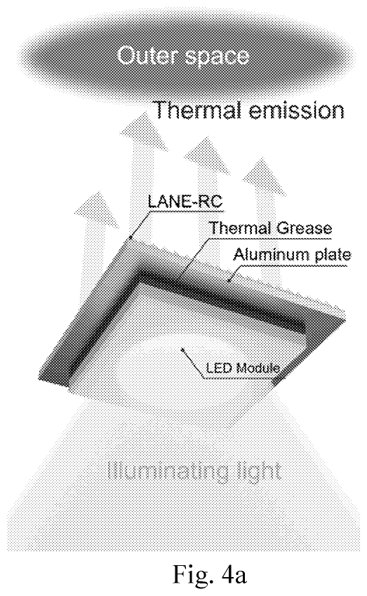

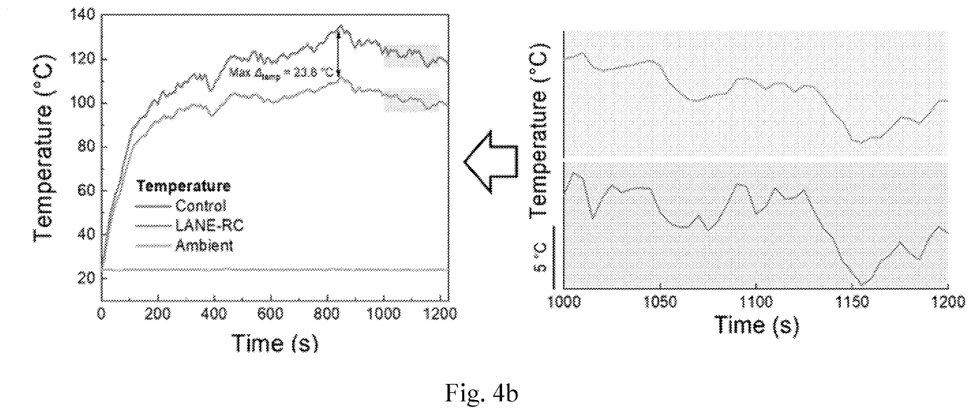

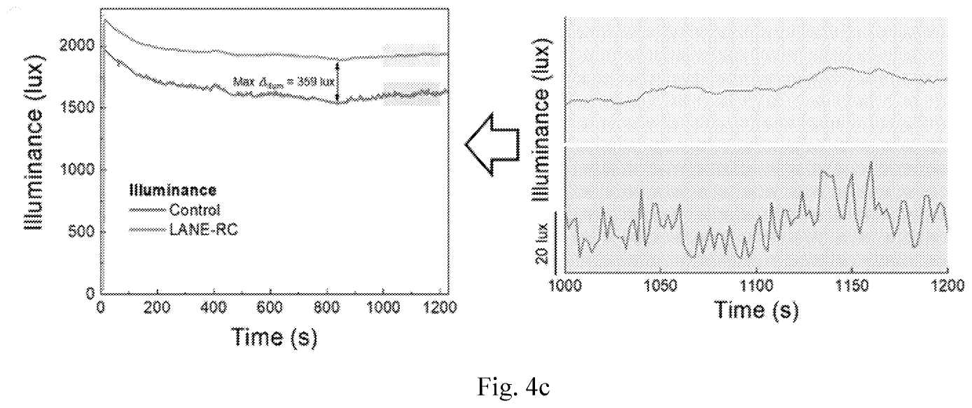

LANE-RC shows near-unit emissivity and it is thin enough to integrate in a compact electronic product for heat dissipation. Here, an experiment is designed to measure the cooling effect on a lighting LED. The experiment setup and the schematic diagram is shown in FIGS. 4a-4c. In FIG. 4a, a LED Module is sticked onto an aluminum plate with thermal grease, and LANE-RC is attached to the other side of the aluminum plate to emit heat to the sky, while there is no adhesion on the aluminum plate of the control group. When a LED is working, 30% of the energy it consumes will be converted into heat energy, and excessive temperature will affect the working efficiency of the LED and even cause it to burn out. Usually, a lighting LED needs a radiator that several times larger than itself to dissipate heat, which increased overall volume of LED. Lighting is often a necessary requirement when hiking outdoors, but the extra volume and weight brought by traditional cooling modes greatly affects its portability. In this experiment, a layer of LANE-EC membrane is covered on an aluminum sheet, which exists as a heat sink in this experiment, and a lighting LED is sticked to the aluminum sheet below with thermal grease, as shown in FIG. 4c. The heat generated by LED will conduct to the aluminum sheet, and the sheet stores part of the heat and conducts it to the LANE-RC covering the upper surface. Then, LANE-RC will radiate heat to the outer space. Another group without LANE-RC coverage will serve as a control. Combined LED experimental assembly was placed on plastic bracket and a illuminometer was placed under the LED to measure the illumination. The temperature is measured with thermal couple which placed on the heat sink. To minimized the influence of heat conduction and conversion, the connecting between assembly and bracket is point contact and an infrared transparent PE layer is covered on the device. To avoid the influence of external lighting from outside, i.e. building lighting in the experiment environment, a black hood is covered around the experimental device, and the two groups of assemble are separated by a black plate to prevent the two groups from interacting with each other.

The result is shown in FIGS. 4b-4c. During the test, the temperature of LENC-RC attached group is significantly lower than that of control. The maximum temperature drop reaches 23.8° C. The illumination of LENC-RC attached group is higher than control in the whole process with a 23.8% improvement in maximum which is marked in FIG. 4b. It intuitively demonstrates the enhancement of lighting LED lighting capabilities and significant temperature control capabilities of LANE-RC. Besides, the attachment of LANE-RC added additional thermal capacity to the system, which helped to stabilize the temperature and illuminance of the system. The addition of LANE-RC significantly improve the temperature stability and illumination stability. In actual situations, the working status of LED is affected by many factors, including environmental factors like wind, or systematic factors such as thermal shock caused by unstable power supply. These effects may cause the instantaneous lighting performance disturbances cause LED strobes, reduce lighting quality, and affect the actual use. Here, LANE-RC can dissipate heat continuously and the additional thermal capacity can reduce the adverse effects of thermal shock, so that improve the overall lighting quality. This experiment proved LANE-RC has a great potential in electronics thermal management, which is mainly due to its near-unit and large angle emissivity.

In summary, one can see that the exemplary embodiments mentioned above provide an LANE-RC with near unity emissivity (>0.99) in the atmospheric window with the assistance of micro-3D printing technology. This cooler combines the excellent light-trapping performance of the surface pyramid structure and the weak angle dependence. characteristics, achieving ultra-high emission performance over a wide range in a hemispheric space. Moreover, this article designed experiments to evaluate its cooling performance and found that it can significantly reduce the operating temperature for 23.8° C. of the lighting LED while increasing the brightness of the lighting LED for ~24% and improving its working efficiency. This result shows that LANE-RC has broad application prospects in the field of radiant cooling of electronic devices, and proves the application possibility of micro-3D printing technology in the field of high-performance radiative cooling.

Key features of the LANE-RC include but not limited to:
Micro-Pyramid Surface Structure: The variable cross-section pyramidal design minimizes reflectance, maximizes absorption efficiency through cavity resonance, and enhances emissivity across a broad angular spectrum.
Material Optimization: Suitable material should be chosen for a high absorption in LWIR, flexibility, and chemical stability.
Fabrication Technique: A 3D-printed template with near-inverted pyramidal structures is used to mold the polymer membrane. According to different application scenarios, the thermal radiator can be directly printed with 3D printing. The precision achieved ensures the replication of high-performance surface structures.
Enhanced Thermal Emission Properties: The radiator demonstrates near-unit emissivity (99.1%) in the atmospheric window, significantly surpassing plain polymer membranes.

Other novel features related to the LANE-RC include but not limited to:
Surface Geometry Innovation: The micro-pyramid structures reduce impedance mismatch by providing gradual refractive index transitions, ensuring enhanced coupling of electromagnetic waves.
Broad Angular Performance: The variable cross-sectional geometry delivers high emissivity over a wide angular range, making the radiator suitable for diverse environmental orientations.
Cavity Resonance Enhancement: By leveraging geometric resonance effects, the structure improves absorption and emission efficiency across specific LWIR bands, especially in regions with high extinction coefficients.
Simplified Fabrication Process: A novel approach using a 3D-printed template combined with FOTS surface treatment ensures accurate replication and scalability.

The exemplary embodiments are thus fully described. Although the description referred to particular embodiments, it will be clear to one skilled in the art that the invention may be practiced with variation of these specific details. Hence this invention should not be construed as limited to the embodiments set forth herein.

While the embodiments have been illustrated and described in detail in the drawings and foregoing description, the same is to be considered as illustrative and not restrictive in character, it being understood that only exemplary embodiments have been shown and described and do not limit the scope of the invention in any manner. It can be appreciated that any of the features described herein may be used with any embodiment. The illustrative embodiments are not exclusive of each other or of other embodiments not recited herein. Accordingly, the invention also provides embodiments that comprise combinations of one or more of the illustrative embodiments described above. Modifications and variations of the invention as herein set forth can be made without departing from the spirit and scope thereof, and, therefore, only such limitations should be imposed as are indicated by the appended claims.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

What is claimed is:

1. A patterned radiator, comprising:
(a) a polymer membrane, and
(b) a first microscale surface structure formed on the polymer membrane.

2. The patterned radiator of claim 1, wherein the polymer membrane is made of polydimethylsiloxane (PDMS).

3. The patterned radiator of claim 1, wherein the first microscale surface structure comprises a plurality of micro-pyramids.

4. The patterned radiator of claim 3, wherein the base angle of each said micro-pyramid equals to or is larger than 54.75°.

5. The patterned radiator of claim 1, wherein the radiator is adapted to achieve an infrared emissivity of greater than 0.95 in an atmosphere window.

6. The patterned radiator of claim 1, wherein the radiator has a thickness of 200 μm or less.

7. The patterned radiator of claim 1, wherein the radiator is flexible and stretchable.

8. A method for fabricating a template for making the patterned radiator of claim 1, the method comprising steps of:
(a) using a 3D printing process the template which comprises a second microscale surface structure; and
(b) surface-treating the template to reduce a demolding force.

9. The method of claim 8, wherein the second microscale surface structure comprises a plurality of inverted micro-pyramids.

10. The method of claim 8, wherein in Step (a), the 3D printing process is a Projection Micro Stereolithography (PμSL) process.

11. The method of claim 8, wherein in Step (b), FOTS (1H,1H,2H,2H-Perfluorooctyltriethoxysilane) is used.

12. A method of producing a patterned radiator of claim 1, comprising the steps of,
(a) providing a template which comprises a plurality of second microscale surface structure;
(b) spin-coating a degassed prepolymer on the template; and
(c) curing and separating a patterned radiator from the template.

13. The method of claim 10, wherein the degassed prepolymer is a degassed PDMS prepolymer.

14. The method of claim 10, wherein the degassed PDMS prepolymer is mixed with a base and a curing agent.
